(19) United States
(12) Patent Application Publication
(10) Pub. No.: US 2025/0126970 A1
(43) Pub. Date: Apr. 17, 2025

(54) Light-Emitting Device, Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Shun Wang, Beijing (CN); Hao Gao, Beijing (CN); Yansong Li, Beijing (CN); Cheng Han, Beijing (CN); Yan Fan, Beijing (CN); Xiangmin Wen, Beijing (CN); Bingwei Yang, Beijing (CN)

(21) Appl. No.: 18/577,969

(22) PCT Filed: Mar. 16, 2023
(86) PCT No.: PCT/CN2023/081956

§ 371 Date: Jan. 9, 2024

(51) Int. Cl. H10K 50/19; H10K 59/35

(52) U.S. Cl. CPC H10K 50/19; H10K 59/35

(57) ABSTRACT

A light-emitting device includes a first electrode; a second electrode; N light-emitting units stacked between the first electrode and the second electrode; and a connection layer disposed between any two adjacent light-emitting units. A peak of an intrinsic spectrum of at least part of light-emitting units is in a range from 400 nm to 480 nm. A sum of peaks of intrinsic spectra of the N light-emitting units is in a range from N×400 nm to N×480 nm; N≥2, and N is a positive integer. A difference between a color coordinate y value of the light-emitting device under a blue image at a preset viewing angle that is in a range from 60° to 75° and a color coordinate y value of the light-emitting device under the blue image at a viewing angle of 0° is in a range from 0 to 0.07.

### CROSS-REFERENCE TO RELATED APPLICATION

This application is the United States national phase of International Application No. PCT/CN2023/081956, filed Mar. 16, 2023, the disclosure of which is hereby incorporated by reference in its entirety.

### BACKGROUND OF THE INVENTION

### Field of the Invention

The present disclosure relates to the field of display technologies, and in particular, to a light-emitting device, a display panel and a display apparatus.

### Description of Related Art

Organic light-emitting diode (OLED) display technology is the technology that uses luminescent materials to emit light driven by current to achieve display. OLED displays have advantages such as ultra-light, ultra-thin, high brightness, wide viewing angle, low voltage, low power consumption, fast response, high definition, shock-resistant, flexible, low cost, simple process, less raw materials, high luminous efficiency and wide temperature range.

### SUMMARY OF THE INVENTION

In an aspect, a light-emitting device is provided. The light-emitting device includes: a first electrode; a second electrode; N light-emitting units stacked between the first electrode and the second electrode; and a connection layer disposed between any two adjacent light-emitting units. A peak of an intrinsic spectrum of at least part of light-emitting units in the N light-emitting units is in a range from 400 nm to 480 nm; a sum of peaks of intrinsic spectra of the N light-emitting units is in a range from N×400 nm to N×480 nm; N is greater than or equal to 2 (N≥2), and N is a positive integer. A difference between a color coordinate y value of the light-emitting device under a blue image at a preset viewing angle that is in a range from 60° to 75° and a color coordinate y value of the light-emitting device under the blue image at a viewing angle of 0° is in a range from 0 to 0.07.

In some embodiments, the color coordinate y value of the light-emitting device under the blue screen at the preset viewing angle is less than 0.07.

In some embodiments, the peak of the intrinsic spectrum of the at least part of light-emitting units is in a range from 450 nm to 470 nm; and the sum of the peaks of the intrinsic spectra of the N light-emitting units is in a range from N×450 nm to N×470 nm.

In some embodiments, in the at least part of light-emitting units, a peak of an intrinsic spectrum of each light-emitting unit is the same, and the peak of the intrinsic spectrum of each light-emitting unit is in a range from 450 nm to 470 nm.

In some embodiments, a full width at half maximum of the intrinsic spectrum of the at least part of light-emitting units is in a range from 10 nm to 30 nm; and a sum of full widths at half maxima of the intrinsic spectra of the N light-emitting units is in a range from N×10 nm to N×30 nm.

In some embodiments, in the at least part of light-emitting units, a full width at half maximum of an intrinsic spectrum of each light-emitting unit is the same, and the full width at half maximum of the intrinsic spectrum of each light-emitting unit is in a range from 10 nm to 30 nm.

In some embodiments, a luminous intensity of the intrinsic spectrum of the at least part of light-emitting units at 490 nm is in a range from 0 to 0.4, and a sum of luminous intensities of the intrinsic spectra of the N light-emitting units at 490 nm is in a range from 0 to N×0.4.

In some embodiments, a number of the N light-emitting units is two, and the two light-emitting units are respectively a first light-emitting unit and a second light-emitting unit, and the first light-emitting unit and the second light-emitting unit are sequentially away from the first electrode; a peak of an intrinsic spectrum of the first light-emitting unit is Δ1, a peak of an intrinsic spectrum of the second light-emitting unit is λ2, and λ1 and λ2 satisfy: 450 nm<λ1<470 nm, 900 nm<(λ1+λ2)<940 nm, and λ1≠λ2; a full width at half maximum of the intrinsic spectrum of the first light-emitting unit is different from a full width at half maximum of the intrinsic spectrum of the second light-emitting unit; the full width at half maximum of the first light-emitting unit is in a range from 10 nm to 30 nm; and a sum of the full width at half maximum of the first light-emitting unit and the full width at half maximum of the second light-emitting unit is in a range from 20 nm to 60 nm.

In some embodiments, a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ1<0.4, 0<(λ1+λ2)<0.8, and λ1=λ2.

In some embodiments, a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ1<0.4, 0<(λ1+λ2)<0.8, and λ1≠λ2.

In some embodiments, a number of the N light-emitting units is two, and the two light-emitting units are respectively a first light-emitting unit and a second light-emitting unit, and the first light-emitting unit and the second light-emitting unit are sequentially away from the first electrode; a peak of an intrinsic spectrum of the first light-emitting unit is λ1, a peak of an intrinsic spectrum of the second light-emitting unit is λ2, and λ1 and λ2 satisfy: 450 nm<λ2<470 nm, 900 nm<(λ1+λ2)<940 nm, and λ1≠λ2; a full width at half maximum of the intrinsic spectrum of the first light-emitting unit is different from a full width at half maximum of the intrinsic spectrum of the second light-emitting unit; the full width at half maximum of the intrinsic spectrum of the second light-emitting unit is in a range from 10 nm to 30 nm; and a sum of the full width at half maximum of the first light-emitting unit and the full width at half maximum of the second light-emitting unit is in a range from 20 nm to 60 nm.

In some embodiments, a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ2<0.4, 0<(λ1+λ2)<0.8, and λ1≠λ2.

In some embodiments, a number of the N light-emitting units is three, and the three light-emitting units are respectively a first light-emitting unit, a second light-emitting unit and a third light-emitting unit; the first light-emitting unit, the second light-emitting unit and the third light-emitting unit are sequentially away from the first electrode; a peak of an intrinsic spectrum of the first light-emitting unit is λ1, a peak of an intrinsic spectrum of the second light-emitting unit is λ2, a peak of an intrinsic spectrum of the third light-emitting unit is λ3, and λ1, λ2 and λ3 satisfy: 450 nm<λ1<470 nm, 1350 nm<(λ1+λ2+λ3)<1410 nm; a full width at half maximum of the intrinsic spectrum of the first light-emitting unit is in a range from 10 nm to 30 nm; a sum of the full width at half maximum of the intrinsic spectrum of the first light-emitting unit, a full width at half maximum of the intrinsic spectrum of the second light-emitting unit and a full width at half maximum of the intrinsic spectrum of the third light-emitting unit is in a range from 30 nm to 90 nm; a luminous intensity of the intrinsic spectrum of the first light-emitting unit at 490 nm is λ1, a luminous intensity of the intrinsic spectrum of the second light-emitting unit at 490 nm is λ2, a luminous intensity of the intrinsic spectrum of the third light-emitting unit at 490 nm is λ3, and λ1, λ2 and λ3 satisfy: 0<λ1<0.4 and 0<(λ1+λ2+λ3)<1.2.

In some embodiments, a peak of an intrinsic spectrum of a light-emitting unit close to the first electrode is in a range from 450 nm to 470 nm; and the sum of the peaks of the intrinsic spectra of the N light-emitting units is in a range from N×450 nm to N×470 nm; a full width at half maximum of the intrinsic spectrum of the light-emitting unit close to the first electrode is in a range from 10 nm to 30 nm; and a sum of full widths at half maxima of the intrinsic spectra of the N light-emitting units is in a range from N×10 nm to N×30 nm; a luminous intensity at 490 nm of the intrinsic spectrum of the light-emitting unit close to the first electrode is in a range from 0 to 0.4, and a sum of luminous intensities of the intrinsic spectra of the N light-emitting units at 490 nm is in a range from 0 to N×0.4.

In some embodiments, the light-emitting device further includes an optical coupling layer located on a side of the second electrode away from the first electrode.

In some embodiments, a thickness of the second electrode is greater than 12 nm; a thickness of the optical coupling layer is h1, a refractive index of the optical coupling layer is n, and h1 and n satisfy: h1×n>150.

In another aspect, a display panel is provided. The display panel includes a substrate and a plurality of sub-pixels disposed on the substrate; at least one sub-pixel includes the light-emitting device as described in any of the above embodiments.

In yet another aspect, a display apparatus is provided. The display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, but are not limitations on actual sizes of products and actual processes of methods involved in the embodiments of the present disclosure.

FIG. 1 is a diagram showing a structure of a display apparatus, in accordance with some embodiments;

FIG. 2 is a diagram showing a structure of a display panel, in accordance with some embodiments;

FIG. 3 is a diagram showing a structure of a display panel, in accordance with some other embodiments;

FIG. 4 is a diagram showing a structure of a light-emitting device, in accordance with some embodiments;

FIG. 5 is a diagram showing a structure of a light-emitting device, in accordance with some other embodiments;

FIG. 6 is a diagram showing a color shift comparison of a light-emitting device and a light-emitting device of a single light-emitting unit, in accordance with some embodiments;

FIG. 7 is a diagram showing a color shift comparison of a light-emitting device and a reference light-emitting device, in accordance with some embodiments;

FIG. 8 is a diagram showing a color shift comparison of a light-emitting device and a reference light-emitting device, in accordance with some other embodiments;

FIG. 9 is a diagram showing a color shift comparison of a light-emitting device and a reference light-emitting device, in accordance with some other embodiments;

FIG. 10 is a diagram showing a color shift comparison of a light-emitting device and a reference light-emitting device, in accordance with some other embodiments;

FIG. 11 is a diagram showing a color shift comparison of a light-emitting device and a reference light-emitting device, in accordance with some other embodiments;

FIG. 12 is a diagram showing a color shift comparison of a light-emitting device and a reference light-emitting device, in accordance with some other embodiments;

FIG. 13 is a diagram showing a color shift comparison of a light-emitting device and a reference light-emitting device, in accordance with some other embodiments; and

FIG. 14 is a diagram showing a color shift comparison of a light-emitting device and a reference light-emitting device, in accordance with some other embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined with the terms such as “first” and “second” may explicitly or implicitly include one or more of the features. In the description of the embodiments of the present disclosure, the term “multiple,” “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

It will be understood that in a case where a layer or component is referred to as being on another layer or a substrate, it may be that the layer or component is directly on the another layer or substrate; or it may be that intermediate layer(s) exist between the layer or component and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

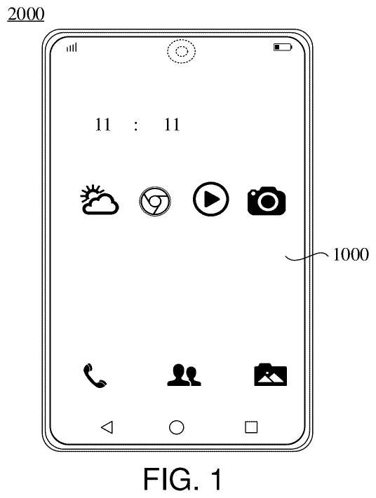

As shown in FIG. 1, some embodiments of the present disclosure provide a display apparatus 2000, and the display apparatus 2000 includes a display panel 1000.

In some examples, the display apparatus 2000 may be, for example, an electroluminescent display apparatus or a photoluminescence display apparatus. In a case where the display apparatus 2000 is an electroluminescent display apparatus, the electroluminescent display apparatus may be an organic light-emitting diode (OLED) display apparatus or a quantum dot light-emitting diode (QLED) display apparatus. In a case where the display apparatus 2000 is a photoluminescent display apparatus, the photoluminescent display apparatus may be a quantum dot photoluminescent display apparatus.

For example, the display apparatus 2000 may further include a driving circuit coupled to the display panel 1000, and the driving circuit is configured to provide electrical signals to the display panel 1000.

For example, the display apparatus 2000 may be any apparatus that displays images whether in motion (e.g., videos) or stationary (e.g., static images), and whether textual or graphical. More specifically, it is contemplated that the display apparatus in the embodiments may be implemented in or associated with various electronic devices. The various electronic devices may include (but is not limit to), for example, mobile phones, wireless devices, personal digital assistants (PDAs), hand-held or portable computers, GPS receivers/navigators, cameras, MP4 video players, video cameras, game consoles, watches, clocks, calculators, television monitors, flat panel displays, computer monitors, car displays (e.g., odometer displays), navigators, cockpit controllers and/or displays, camera view displays (e.g., rear view camera displays in vehicles), electronic photos, electronic billboards or signages, projectors, architectural structures, packaging and aesthetic structures (e.g., displays for images of a piece of jewelry).

Some embodiments of the present disclosure provide a display panel 1000, and the display panel 1000 can be applied to the above-mentioned display apparatus 2000. Of course, the display panel 1000 can also be applied to other display apparatuses, which will not be limited in the present disclosure.

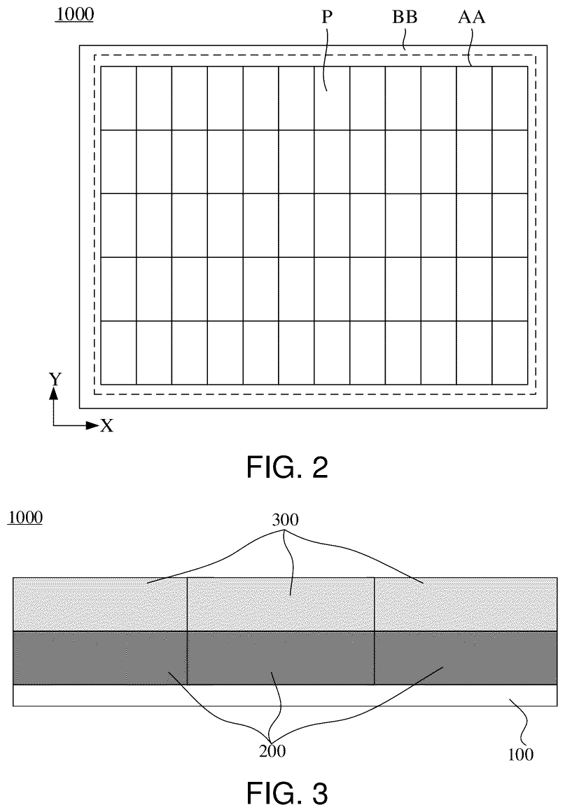

In some embodiments, as shown in FIG. 2, the display panel 1000 has a display region AA and a peripheral region BB located on at least one side of the display region AA.

In some examples, referring to FIG. 2, the peripheral region BB is arranged around the display region AA.

The display region AA is a region for displaying images. The display region AA is provided therein with sub-pixels P of multiple colors; the sub-pixels P of multiple colors include at least sub-pixels of a first color, sub-pixels of a second color and sub-pixels of a third color; and the first color, the second color and the third color may be three primary colors (such as red, green and blue). A region of any sub-pixel P can be defined by a pixel definition layer. The peripheral region BB is a region where structures such as scan driving circuit(s), circuit traces, and bonding pins are arranged.

For example, referring to FIG. 2, a plurality of sub-pixels P are arranged in rows and columns. Each row of sub-pixels P may include multiple sub-pixels P that are arranged along a first direction X, and each column of sub-pixels P may include multiple sub-pixels P that are arranged along a second direction Y.

In some embodiments, as shown in FIG. 3, the display panel 1000 includes a substrate 100, a plurality of pixel circuits 200 disposed on a side of the substrate 100, and a plurality of light-emitting devices 300 disposed on a side of the plurality of pixel circuits 200 away from the substrate 100.

In some example, the type of the substrate 100 varies, which can be set according to actual needs.

For example, the substrate 100 may be a flexible substrate or a rigid substrate.

For example, when the substrate 100 is a flexible substrate, the substrate 100 may be made of dimethylsiloxane, polyimide (PI), polyethylene terephthalate (PET) or other highly elastic materials.

As another example, when the substrate 100 is a rigid substrate, the substrate 100 may be made of glass or the like.

In some examples, each sub-pixel P includes a light-emitting device 300 and a pixel circuit 200.

The structure of the pixel circuit 200 varies, which may be set according to actual needs. For example, the pixel circuit 200 includes at least two transistors and at least one capacitor. For example, the pixel circuit 200 may be of a structure with “6T1C,” “7T1C,” “6T2C,” or “7T2C”. Here, “T” represents a transistor, the number preceding “T” represents the number of transistors, “C” represents a capacitor, and the number preceding “C” represents the number of capacitors.

The pixel circuit 200 is electrically connected to the light-emitting device 300, and the connection relationship between the two may vary, which may be set according to actual needs and will not be limited in the present disclosure.

For example, the pixel circuits 200 and the light-emitting devices 300 are electrically connected in one-to-one correspondence. As another example, a single pixel circuit 200 may be electrically connected to multiple light-emitting devices 300. As another example, multiple pixel circuits 200 may be electrically connected to a single light-emitting device 300.

Hereinafter, in the embodiments of the present disclosure, the structure of the display panel 1000 will be schematically described by taking an example in which a single pixel circuit 200 is coupled to a single light-emitting device 300.

It can be understood that a pixel circuit 200 can generate a driving signal and transmit the driving signal to a corresponding light-emitting device 300 to control a light-emitting state of the light-emitting device 300. The light-emitting state includes, for example, whether the light-emitting device 300 emits light, or the light-emitting brightness of the light-emitting device 300. The plurality of pixel circuits 200 jointly control the light-emitting states of the plurality of light-emitting devices 300, and the light emitted by the plurality of light-emitting devices 300 cooperates, thereby enabling the display panel 1000 to display images.

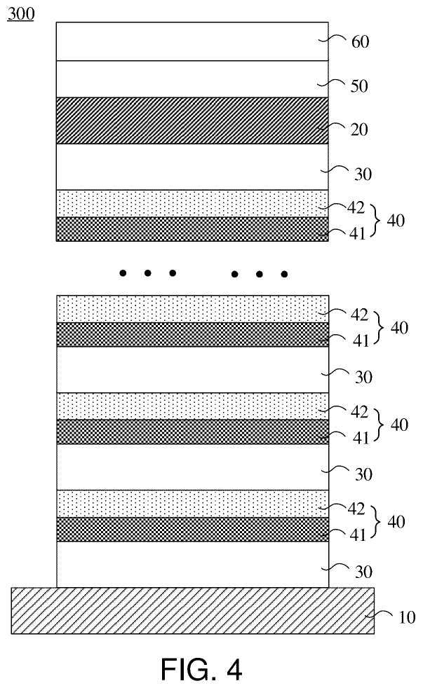

In some embodiments, as shown in FIG. 4, the light-emitting device 300 includes: a first electrode 10, a second electrode 20, N light-emitting units 30 stacked between the first electrode 10 and the second electrode 20, and a connection layer 40 disposed between any two adjacent light-emitting units 30. Here, N is greater than or equal to 2 (N 2), and N is an integer.

In some examples, the first electrode 10 is an anode, and the second electrode 20 is a cathode.

The material of the anode may include a transparent conductive oxide material, or the material of the anode may also include a metal material. The transparent conductive oxide material is, for example, indium tin oxide (ITO) or indium zinc oxide (IZO); the metal material is, for example, gold (Au), silver (Ag), nickel (Ni), or platinum (Pt). In some examples, the anode is a conductive layer made of a transparent conductive oxide.

In some other examples, the anode is of a stacked composite structure of transparent conductive oxide/metal/transparent conductive oxide. For example, the anode is of a stacked composite structure of ITO/Ag/ITO.

The cathode may be made of metal and/or alloy. The metal material is, for example, λ1, Ag, and Mg; the alloy material is, for example, Mg:Ag alloy (that is, an alloy of Mg and Ag), and Al:Li alloy (that is, an alloy of λ1 and Li).

In some examples, the first electrode 10 is a reflective electrode, and the second electrode 20 is a transparent electrode or a translucent electrode. In this case, the first electrode 10 may be the anode, and the structure of the anode may be the above-mentioned stacked composite structure of ITO/Ag/ITO in which the metal Ag layer is a reflective layer. At this time, the light-emitting device 300 is a top-emission light-emitting device, and light emitted by the N light-emitting units 30 exits toward a side away from the first electrode 10 (i.e., the anode).

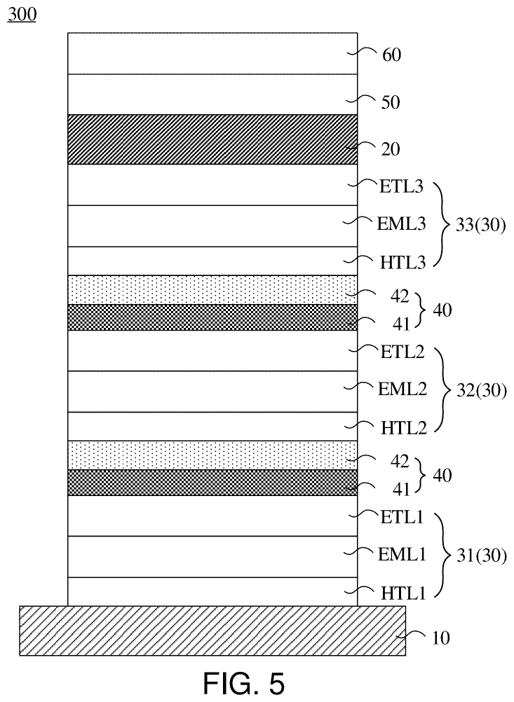

In some examples, the number of light-emitting units 30 may be two, three, or other numbers, which is not limited here. For example, as shown in FIG. 4, FIG. 4 illustrates a plurality of light-emitting units 30. As another example, as shown in FIG. 5, FIG. 5 illustrates three light-emitting units 30.

In some examples, as shown in FIG. 5, the N light-emitting units 30 between the first electrode 10 and the second electrode 20 include at least a first light-emitting unit 31 and a second light-emitting unit 32. The first light-emitting unit 31 and the second light-emitting unit 32 are away from the first electrode 10 in sequence. That is, the first light-emitting unit 31 is located between the second light-emitting unit 32 and the first electrode 10. For example, the first light-emitting unit 31 is in direct contact with the first electrode 10, and the second light-emitting unit 32 is in direct contact with the second electrode 20.

In some examples, as shown in FIG. 5, the first light-emitting unit 31 includes a first light-emitting layer EML1. For example, the first light-emitting layer EML1 is a blue light-emitting layer used for emitting blue light.

For example, the material of the first light-emitting layer EML1 includes anthracene compounds, fluorene compounds, styrene compounds, etc.

Optionally, the first light-emitting unit 31 further includes at least one of a first hole injection layer, a first hole transport layer, a first electron blocking layer, a first hole blocking layer, a first electron transport layer, or a first electron injection layer.

The first electron injection layer can reduce the injection barrier of electrons, the first electron transport layer can improve the transportability of electrons, the first electron blocking layer can hinder the transportability of electrons, and the first hole blocking layer can hinder the transportability of holes, the first hole transport layer can improve the transportability of holes, and the first hole injection layer can reduce the injection barrier of holes.

Optionally, the thickness of the first electron injection layer included in the first light-emitting unit 31 may be in a range from 1 nm to 3 nm, the thickness of the first electron transport layer may be in a range from 20 nm to 35 nm, and the thickness of the first hole blocking layer may be in a range from 5 nm to 10 nm, the thickness of the first light-emitting layer EML1 may be in a range from 20 nm to 40 nm, the thickness of the first electron blocking layer may be in a range from 10 nm to 80 nm, the thickness of the first hole transport layer may be in a range from 1000 nm to 1300 nm, and the thickness of the first hole injection layer may be in a range from 5 nm to 30 nm. If the thicknesses of all layers change within the above thickness ranges, the color of the emitted light will change within the same color system. For example, when the light emitted by the first light-emitting layer EML1 is blue light and the thickness of the first electron transport layer ETL1 is 30 nm, if the thickness of the first electron transport layer ETL1 changes from 30 nm to 25 nm, then the light emitted by the first light-emitting layer EML1 may change from blue to light blue color; correspondingly, if the thickness of the first electron transport layer ETL1 changes from 30 nm to 33 nm, then the light emitted by the first light-emitting layer EML1 may change from blue to dark blue.

For example, as shown in FIG. 5, the first light-emitting unit 31 further includes a first electron transport layer ETL1 and a first hole transport layer HTL1. The first electron transport layer ETL1 is located between the second light-emitting unit 32 and the first light-emitting layer EML1. The first electron transport layer ETL1 is used for transporting electrons to the first light-emitting layer EML1. The first hole transport layer HTL1 is located between the light-emitting layer EML1 and the first electrode 10. The first hole transport layer HTL1 is used for transporting holes from the first electrode 10 to the first light-emitting layer EML1. In this way, holes and electrons can recombine in the first light-emitting layer EML1, so that the first light-emitting layer EML1 emits light.

The first electron transport layer ETL1 may be a zinc oxide-based nanoparticle film or a zinc oxide film. In addition, in a case where the first electron transport layer ETL1 is a zinc oxide-based nanoparticle film, the first electron transport layer ETL1 can also use ion-doped zinc oxide nanoparticles, such as magnesium (Mg), indium (In), aluminum (Al), gallium (Ga) doped magnesium oxide nanoparticles.

The material of the first hole transport layer HTL1 may include at least one of molybdenum oxide, nickel oxide, zirconium oxide or vanadium oxide, which is not specifically limited in the embodiments of the present disclosure. It should be noted that molybdenum oxide includes molybdenum oxide, molybdenum dioxide and molybdenum trioxide, and nickel oxide includes nickel oxide and nickel trioxide. Zirconium oxide includes zirconium dioxide. Vanadium oxide includes vanadium monoxide, vanadium trioxide, vanadium dioxide, and vanadium pentoxide, which will not be limited in the embodiments of the present disclosure.

The second light-emitting unit 32 includes a second light-emitting layer EML2. For example, the second light-emitting layer EML2 is a blue light-emitting layer used for emitting blue light.

For example, the material of the second light-emitting layer EML2 may include anthracene compounds, fluorene compounds, styrene compounds, etc.

Optionally, the second light-emitting unit 32 further includes at least one of a second hole injection layer, a second hole transport layer, a second electron blocking layer, a second hole blocking layer, a second electron transport layer, or a second electron injection layer.

The second electron injection layer can reduce the injection barrier of electrons, the second electron transport layer can improve the transportability of electrons, the second electron blocking layer can hinder the transportability of electrons, and the second hole blocking layer can hinder the transportability of holes, the second hole transport layer can improve the transportability of holes, and the second hole injection layer can reduce the injection barrier of holes.

Optionally, the thickness of the second electron injection layer included in the second light-emitting unit 32 may be in a range from 1 nm to 3 nm, the thickness of the second electron transport layer may be in a range from 20 nm to 35 nm, the thickness of the second hole blocking layer may be in a range from 5 nm to 10 nm, the thickness of the second light-emitting layer EML2 may be in a range from 20 nm to 40 nm, the thickness of the second electron blocking layer may be in a range from 10 nm to 80 nm, the thickness of the second hole transport layer may be in a range from 1000 nm to 1300 nm, and the thickness of the second hole injection layer may be in a range from 5 nm to 30 nm. If the thicknesses of all layers change within the above thickness ranges, the color of the emitted light will change within the same color system. For example, when the light emitted by the second light-emitting layer EML2 is blue light and the thickness of the second electron transport layer ETL2 is 30 nm, if the thickness of the second electron transport layer ETL2 changes from 30 nm to 25 nm, then the light emitted by the second light-emitting layer EML2 may change from blue to light blue; correspondingly, if the thickness of the second electron transport layer ETL2 changes from 30 nm to 33 nm, then the light emitted by the second light-emitting layer EML2 may change from blue to dark blue.

For example, as shown in FIG. 5, the second light-emitting unit 32 further includes a second electron transport layer ETL2 and a second hole transport layer HTL2. The second electron transport layer ETL2 is located between the second light-emitting layer EML2 and the second electrode 20, and the second electron transport layer ETL2 is used for transporting electrons from the second electrode 20 to the second light-emitting layer EML2. The second hole transport layer HTL2 is located between the second light-emitting layer EML2 and the first light-emitting unit 31. The second hole transport layer HTL2 is used for transporting holes to the second light-emitting layer EML2. In this way, holes and electrons can recombine in the second light-emitting layer EML2, so that the second light-emitting layer EML2 emits light.

The second electron transport layer ETL2 may be a zinc oxide-based nanoparticle film or a zinc oxide film. In addition, when the second electron transport layer ETL2 is a zinc oxide-based nanoparticle film, the second electron transport layer ETL2 may also use ion-doped zinc oxide nanoparticles, such as magnesium (Mg), indium (In), aluminum (Al), gallium (Ga) doped magnesium oxide nanoparticles.

The material of the second hole transport layer HTL2 may include at least one of molybdenum oxide, nickel oxide, zirconium oxide or vanadium oxide, which is not specifically limited in the embodiment of the present disclosure. It should be noted that molybdenum oxide includes molybdenum oxide, molybdenum dioxide and molybdenum trioxide, and nickel oxide includes nickel oxide and nickel trioxide. Zirconium oxide includes zirconium dioxide. Vanadium oxide includes vanadium monoxide, vanadium trioxide, vanadium dioxide, and vanadium pentoxide, which will not be limited in the embodiments of the present disclosure.

For example, the structures of the first light-emitting unit 31 and the second light-emitting unit 32 may be the same or different, which will not be limited in the embodiments of the present disclosure. For example, as shown in FIG. 5, the first light-emitting device 31 and the second light-emitting device 32 have the same structure.

For example, N light-emitting units 30 in the same light-emitting device 300 emit light of the same or similar color. In this way, the concentration of spectral superposition of a plurality of light-emitting units 30 in the same light-emitting device 300 can be improved, and the color purity and light-emitting efficiency of the light emitted by the light-emitting device 300 can be improved.

It should be noted that the “light-emitting efficiency” mentioned herein is an index for evaluating a light-emitting device, and can be characterized by at least one of quantum efficiency, power efficiency, or current efficiency. The quantum efficiency is a ratio of the number of photons generated by the light-emitting device 300 to the total number of injected carriers; the quantum efficiency is classified into internal quantum efficiency and external quantum efficiency, and the unit is percentage (%). The external quantum efficiency refers to a ratio of the total number of photons emitted by the light-emitting device 300 to the number of injected carriers; and the internal quantum efficiency refers to a ratio of the total number of photons generated in the light-emitting device 300 to the number of injected carriers. The current efficiency refers to a ratio of the light-emitting brightness of the light-emitting device 300 to the current density, and the unit is candela per ampere (cd·A⁻¹). The power efficiency refers to a ratio of the optical power output by the light-emitting device 300 to the input power, and the unit is lumens per watt (Im·W⁻¹).

In some examples, as shown in FIGS. 4 and 5, the connection layer 40 includes an N-type charge generation layer 41 and a P-type charge generation layer 42 that are stacked.

For example, as shown in FIG. 5, the above-mentioned connection layer 40 is provided between the first light-emitting unit 31 and the second light-emitting unit 32. The N-type charge generation layer 41 is in direct contact with the first light-emitting unit 31 and can provide electrons to the first light-emitting unit 31. The P-type charge generation layer 42 is in direct contact with the second light-emitting unit 32 and can provide holes to the second light-emitting unit 32.

The materials of the N-type charge generation layer 41 and the P-type charge generation layer 42 may each include metal, non-doped organic matter, P-type and N-type doped organic PN junction or metal oxide, which are not limited here.

For example, the first light-emitting unit 31 and the second light-emitting unit 32 are connected in series through the connection layer 40, which effectively improves the light-emitting efficiency of the light-emitting device 300 and extends the service life of the light-emitting device 300. In addition, the light-emitting efficiency of the light-emitting device 300 increases as the number of the light-emitting units 30 increases, which may increase exponentially. Under the same brightness, the life of the light-emitting device 300 increases exponentially.

As the size of the display panel 1000 gradually increases, the range of the viewing angle of the user also increases accordingly. However, under a large viewing angle, the display panel 1000 is prone to color shift.

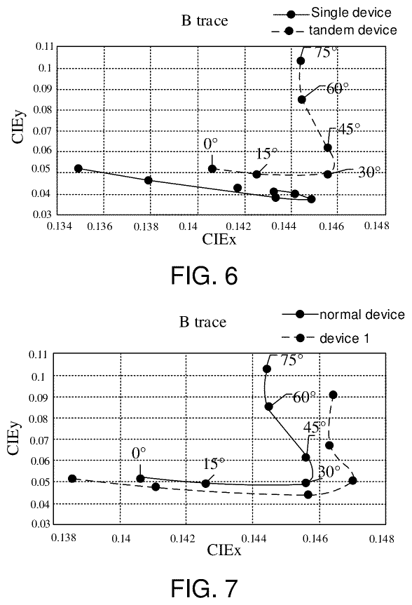

The inventors of the present disclosure have found through research that compared with a light-emitting device that includes a single light-emitting unit (for example, the Single device in FIG. 6), a light-emitting device 300 that includes a plurality of light-emitting units 30 connected in series (for example, the tandem device in FIG. 6) has more serious color shift and a poor display effect of monochrome images under a large viewing angle. That is, compared with the light-emitting device that includes a single light-emitting unit, a color coordinate y value (i.e., CIEy) of the light-emitting device 300 that includes a plurality of light-emitting units 30 connected in series under a blue image at a large viewing angle is more deviated from a color coordinate y value (i.e., CIEy) of the light-emitting device 300 under a blue image at a viewing angle of 0°.

Considering a blue light-emitting device as an example, as shown in FIG. 6, when the light-emitting device 300 includes a plurality of light-emitting units 30 connected in series (i.e., the tandem device in the figure), the color coordinate y value of the light-emitting device under the blue image at the viewing angle of 60° is greater than 0.07, and the color coordinate y value of the light-emitting device under the blue image at the viewing angle of 75° is greater than 0.09. Therefore, the blue image tends to turn white when viewed at a viewing angle of 60° or 75°, which affects the viewing effect of the user.

The inventors of the present disclosure further found that when the viewing angle of the user increases from 0° to 60°, the device efficiency attenuation of the blue light-emitting device is more obvious, and the device efficiency attenuation of the green light-emitting device and the device efficiency attenuation of the red light-emitting device is less obvious.

Based on this, in some embodiments of the present disclosure, the light-emitting device 300 includes a first electrode 10, a second electrode 20, and N light-emitting units 30 stacked between the first electrode 10 and the second electrode 20; a peak of an intrinsic spectrum of at least part of light-emitting units 30 is in a range from 400 nm to 480 nm; and a sum of peaks of intrinsic spectra of the N light-emitting units 30 is in a range from N×400 nm to N×480 nm. The color coordinate y value (i.e., CIEy) of the light-emitting device 300 under the blue image when the preset viewing angle is in a range from 60° to 75° and the color coordinate y value (i.e., CIEy) of the light-emitting device 300 under the blue image at the viewing angle of 0° have a difference in a range from 0 to 0.07.

It should be noted that in the embodiments of the present disclosure, the peak of the intrinsic spectrum of the light-emitting unit 30 refers to the maximum value of the intrinsic spectrum of the light-emitting unit 30, that is, the wavelength corresponding to the highest point of the intrinsic spectrum of the light-emitting unit 30.

For example, the above-mentioned preset viewing angle may be a large angle viewing angle such as 60°, 63°, 66°, 69° or 75°.

In some examples, the peaks of the intrinsic spectra of the N light-emitting units 30 included in the light-emitting device 300 are each in a range from 400 nm to 480 nm. For example, the peaks of the intrinsic spectra of the N light-emitting units 30 is each 400 nm, 415 nm, 430 nm, 455 nm or 480 nm, etc. The peaks of the intrinsic spectra of the N light-emitting units 30 may be the same or different, which will not be limited in the embodiments of the present disclosure.

In this case, the N light-emitting units 30 are all used for emitting blue light. Therefore, it may be possible to improve the concentration of spectral superposition of a plurality of light-emitting units 30 in the same light-emitting device 300, and improve the color purity of the light emitted by the light-emitting device 300 and the light extraction efficiency.

In some other examples, a peak of an intrinsic spectrum of a part of light-emitting units 30 in the N light-emitting units 30 included in the light-emitting device 300 is in a range from 400 nm to 480 nm. For example, the peak of the intrinsic spectrum of the part of light-emitting units 30 in the N light-emitting units 30 may be 400 nm, 415 nm, 430 nm, 455 nm or 480 nm, etc. The peak of the intrinsic spectrum of the part of light-emitting units 30 in the N light-emitting units 30 may be the same or different, which will not be limited in the embodiments of the present disclosure.

In this case, the part of light-emitting units 30 in the N light-emitting units 30 is used for emitting blue light, and the color of the light emitted by other light-emitting units 30 in the N light-emitting units 30 may be a complementary color of blue. For example, the color of light emitted by other light-emitting units 30 in the N light-emitting units 30 may be red, orange, yellow, etc.

In some examples, the color coordinate y value of the light-emitting device 300 under the blue image at a viewing angle of 0° is generally in a range from 0.03 to 0.07. The color coordinate y value of the light-emitting device 300 under the blue image at a preset viewing angle of 60° is less than or equal to 0.07; in this case, the color coordinate y value of the light-emitting device 300 under the blue image at the preset viewing angle (i.e., 60°) and the color coordinate y value of the light-emitting device 300 under the blue image at the viewing angle of 0° have a difference that is less than or equal to 0.04. The color coordinate y value of the light-emitting device 300 under the blue image at the preset viewing angle of 75° is less than or equal to 0.1; in this case, the color coordinate y value of the light-emitting device 300 under the blue image at the preset viewing angle (i.e., 75°) and the color coordinate y value of the light-emitting device 300 under the blue image at the viewing angle of 0° have a difference that is less than or equal to 0.07. Obviously, the difference between the color coordinate y value of the light-emitting device 300 under the blue image when the preset viewing angle is in a range from 60° to 75° and the color coordinate y value of the light-emitting device 300 under the blue image at the viewing angle of 0° is small.

It should be noted that the CIE 1931 XYZ color space (also called CIE 1931 color space) is the first color space to be defined mathematically, which was founded in 1931 by the International Commission on Illumination (CIE).

The CIE xyY chromaticity diagram is a color space directly derived from the XYZ coordinate system, which uses color coordinates x and y to describe color. The Y value in xyY represents brightness of color or luminance. Color coordinates x and y are used to specify colors on a two-dimensional diagram. This chromaticity diagram is called the CIE1931 chromaticity diagram.

Color space refers to describing the perception of colors on the human eye in an objective way, usually requiring tristimulus values. More specifically, the three primary colors are firstly defined, and then various colors will be described using a color superposition model.

In the three-color additive model, if a certain color and another color that is mixed with different components of the three primary colors look the same to humans, the components of the three primary colors will be called tristimulus values of the color. The CIE 1931 color space usually provides tristimulus values of a color which are expressed in terms of X, Y and Z.

In this embodiment, the difference between the color coordinate y value of the light-emitting device 300 under the blue image at the preset viewing angle of 60° to 75° and the color coordinate y value of the light-emitting device 300 under the blue image at the viewing angle of 0° is in a range from 0 to 0.07, which ensures that the color coordinate y value of the light-emitting device 300 under the blue image at a large viewing angle is within a small range, thus effectively ameliorating the color shift of the display panel 1000 at the preset viewing angle and improving the viewing effect of the viewer.

In some embodiments, the color coordinate y value of the light-emitting device 300 under the blue image at the above-mentioned preset viewing angle is less than 0.07.

For example, when the above-mentioned preset viewing angle is 60°, the color coordinate y value of the light-emitting device 300 under the blue image is less than 0.07.

For example, when the above-mentioned preset viewing angle is 60°, the color coordinate y value of the light-emitting device 300 under the blue image may be 0.05, 0.055, 0.06, 0.065 or 0.069.

It can be seen from the above that when the color coordinate y value of the light-emitting device 300 under the blue image at the viewing angle of 60° is greater than 0.07, the image at a large viewing angle tends to become white. In this implementation, the color coordinate y value of the light-emitting device 300 under the blue image at the preset viewing angle is less than 0.07, which may effectively ameliorate the color shift of the image at the large viewing angle and improve the viewing effect of the viewer.

In some embodiments, the peak of the intrinsic spectrum of the at least part of light-emitting units 30 is in a range from 450 nm to 470 nm; and the sum of the peaks of the intrinsic spectra of the N light-emitting units 30 is in a range from N×450 nm to N×470 nm.

In some examples, a peak of an intrinsic spectrum of part of light-emitting units 30 in the N light-emitting units 30 is in a range from 450 nm to 470 nm. For example, the peak of the intrinsic spectrum of the part of light-emitting units 30 in the N light-emitting units 30 may be 450 nm, 455 nm, 460 nm, 465 nm, 470 nm, etc., which is not limited in the embodiments of the present disclosure.

In some other examples, a peak of an intrinsic spectrum of each light-emitting unit 30 of the N light-emitting units 30 is in a range from 450 nm to 470 nm. For example, the peak of the intrinsic spectrum of each light-emitting unit 30 of the N light-emitting units 30 is 450 nm, 455 nm, 460 nm, 465 nm, or 470 nm, which is not limited in the embodiments of the present disclosure.

For example, when the N light-emitting units 30 include the first light-emitting unit 31 and the second light-emitting unit 32, the peaks of the intrinsic spectra of the first light-emitting unit 31 and the second light-emitting unit 32 may all be in a range from 450 nm to 470 nm; alternatively, the peak of the intrinsic spectrum of one of the first light-emitting unit 31 and the second light-emitting unit 32 is in a range from 450 nm to 470 nm, and the sum of the peaks of the intrinsic spectra of the first light-emitting unit 31 and the second light-emitting unit 32 is in a range from 2×450 nm to 2×470 nm.

For example, the peaks of the intrinsic spectra of all light-emitting units 30 in the part of light-emitting units 30 mentioned above may be the same or different, which will not be limited in the embodiments of the present disclosure.

Those skilled in the art can understand that according to the spectrum of the tristimulus values, it can be inferred that when the wavelength corresponding to the peak of the intrinsic spectrum of the light-emitting unit 30 is small, the spectral enhancement at the main peak position of the spectrum of the light-emitting device 300 will be more obvious; correspondingly, the spectral enhancement at the non-main peak position of the spectrum of the light-emitting device 300 will be weakened. In this embodiment, since the peak of the intrinsic spectrum of the at least part of light-emitting units 30 is in a range from 450 nm to 470 nm, the wavelength corresponding to the peak of the intrinsic spectrum of the at least part of light-emitting units 30 is small. Therefore, the spectral enhancement at the main peak position of the spectrum of the light-emitting device 300 is more obvious; correspondingly, the spectral enhancement at the non-main peak position of the spectrum of the light-emitting device 300 will be weakened. As a result, the color shift of the display panel 1000 at a large viewing angle is reduced, which improves the viewing effect of the viewer.

In some embodiments, in the at least part of light-emitting units 30 mentioned above, the peak of the intrinsic spectrum of each light-emitting units 30 is the same, and the peak of the intrinsic spectrum of the light-emitting units 30 is in a range from 450 nm to 470 nm.

For example, in the at least part of light-emitting units 30, the peak of the intrinsic spectrum of each light-emitting unit 30 is 450 nm, 455 nm, 460 nm, 465 nm or 470 nm, which is not limited in the embodiments of the present disclosure.

For example, the peaks of the intrinsic spectra of the N light-emitting units 30 are all in a range from 450 nm to 470 nm, for example, it may be that the peak of the intrinsic spectrum of each of the N light-emitting units 30 are the same, and the peak of the intrinsic spectrum of each of the N light-emitting units 30 is in a range from 450 nm to 470 nm.

In this way, it can further ameliorate the problem that the image of the display panel 1000 is prone to color shift at a large viewing angle, improve the display effect of the display panel 1000 at a large viewing angle, and improve the viewing effect of the viewer.

In some embodiments, a full width at half maximum (FWHM) of the intrinsic spectrum of the at least part of light-emitting units 30 is in a range from 10 nm to 30 nm; and a sum of FWHMs of the intrinsic spectra of the N light-emitting units 30 is in a range from N×10 nm to N×30 nm.

In some examples, a FWHM of the intrinsic spectrum of the part of light-emitting units 30 in the N light-emitting units 30 is in a range from 10 nm to 30 nm. In some other examples, a FWHM of a peak of an intrinsic spectrum of each light-emitting unit 30 of the N light-emitting units 30 is in a range from 10 nm to 30 nm. The embodiments of the present disclosure are not limited to this.

For example, when the N light-emitting units 30 include the first light-emitting unit 31 and the second light-emitting unit 32, the FWHMs of the intrinsic spectra of the first light-emitting unit 31 and the second light-emitting unit 32 may be in a range from 10 nm to 30 nm; alternatively, the FWHM of the intrinsic spectrum of one of the first light-emitting unit 31 and the second light-emitting unit 32 is in a range from 10 nm to 30 nm, and the sum of the FWHMs of the intrinsic spectra of the first light-emitting unit 31 and the second light-emitting unit 32 is in a range from 2×10 nm to 2×30 nm.

For example, the FWHM of the intrinsic spectrum of each light-emitting unit 30 may be the same or different, which is not limited in the embodiments of the present disclosure.

For example, the FWHM of the intrinsic spectrum of the at least part of light-emitting units 30 may be 10 nm, 15 nm, 20 nm, 25 nm or 30 nm, etc., which is not limited in the embodiments of the present disclosure.

Those skilled in the art can understand that in the graph of the intrinsic spectrum of the light-emitting unit 30, the spectral width to the right of the peak of the intrinsic spectrum of the light-emitting unit 30 is wider than the spectral width to the left of the peak of the intrinsic spectrum of the light-emitting unit 30. In this embodiment, the FWHM of the intrinsic spectrum of the at least part of light-emitting units 30 is in a range from 10 nm to 30 nm. Compared with a FWHM of an intrinsic spectrum of a general light-emitting device, in this embodiment, the FWHM of the intrinsic spectrum of the at least part of light-emitting units 30 decreases. In this case, the spectral width to the right of the peak of the intrinsic spectrum of the light-emitting unit 30 and the spectral width to the left of the peak of the intrinsic spectrum of the light-emitting unit 30 both decrease, and the spectral width to the right of the peak of the intrinsic spectrum of the light-emitting unit 30 changes more and decreases more than the spectral width to the left of the peak of the intrinsic spectrum of the light-emitting unit 30. Therefore, the non-main peak position of the intrinsic spectrum of the light-emitting device 300 moves closer to the left of the peak of the intrinsic spectrum. That is, the wavelength corresponding to the non-main peak position of the intrinsic spectrum of the light-emitting device 300 decreases. In this way, the enhancement of the intrinsic spectrum of the light-emitting device 300 at the non-main peak position of the spectrum of the light-emitting device 300 becomes weaker, thereby reducing the color shift of the light-emitting device 300 and improving the viewing effect of the viewer.

In some embodiments, in the at least part of light-emitting units 30, the FWHM of the intrinsic spectrum of each light-emitting unit 30 is the same, and the FWHM of the intrinsic spectrum of each light-emitting unit 30 is in a range from 10 nm to 30 nm.

For example, the FWHM of the intrinsic spectrum of each light-emitting unit 30 in the at least part of light-emitting units 30 is 10 nm, 15 nm, 20 nm, 25 nm or 30 nm, which is not limited in the embodiments of the present disclosure.

For example, when the FWHMs of the peaks of the intrinsic spectra of the N light-emitting units 30 are all in a range from 10 nm to 30 nm, for example, it may be that the FWHM of the peak of the intrinsic spectrum of each of the N light-emitting units 30 is the same, and the FWHM of the peak of the intrinsic spectrum of each of the N light-emitting units 30 is in a range from 10 nm to 30 nm.

In this way, it can further ameliorate the problem of color shift in the image at a large viewing angle, improve the display effect of the display panel 1000 at a large viewing angle, and improve the viewing effect of the viewer. On this basis, the light-emitting efficiency of the light-emitting device 300 can also be effectively improved.

In some embodiments, the luminous intensity of the intrinsic spectrum of the at least part of light-emitting units 30 at 490 nm is in a range from 0 to 0.4, and the sum of the luminous intensities of the intrinsic spectra of the N light-emitting units 30 at 490 nm are in a range from 0 to N×0.4.

It should be noted that the luminous intensity refers to a relative intensity of the luminous intensity of the intrinsic spectrum of the light-emitting unit 30 at 490 nm relative to the luminous intensity of the intrinsic spectrum of the light-emitting unit 30 at the peak.

Optionally, in the embodiments of the present disclosure, the luminous intensity of the intrinsic spectrum of the light-emitting unit 30 at 490 nm can also refer to the luminous intensity of the intrinsic spectrum of the light-emitting unit 30 at 490 nm after a spectrum measured by a spectrometer has undergone a normalization processing.

Here, the normalization processing of the spectrum means that the luminous intensity of the intrinsic spectrum of the light-emitting unit 30 at the peak is set to one, and the luminous intensity of the intrinsic spectrum of the light-emitting unit 30 at 490 nm is a luminous intensity presented in the same coordinate system.

Optionally, the luminous intensity of the intrinsic spectrum of the at least part of light-emitting units 30 at 490 nm is not equal to 0.

In some examples, the luminous intensity of the intrinsic spectrum of the part of light-emitting units 30 in the N light-emitting units 30 at 490 nm is in a range from 0 to 0.4. In some examples, the luminous intensities of the intrinsic spectra of the N light-emitting units 30 at 490 nm are all in a range from 0 to 0.4. The embodiments of the present disclosure are not limited to this.

For example, when the N light-emitting units 30 include the first light-emitting unit 31 and the second light-emitting unit 32, the luminous intensity of the intrinsic spectrum of each of the first light-emitting unit 31 and the second light-emitting unit 32 at 490 nm may be in a range from 0 to 0.4; alternatively, the luminous intensity of the intrinsic spectrum of one of the first light-emitting unit 31 and the second light-emitting unit 32 at 490 nm is in a range from 0 to 0.4, and the sum of the luminous intensities of the intrinsic spectra of the first light-emitting unit 31 and the second light-emitting unit 32 at 490 nm is in a range from 0 to N×0.4.

For example, the luminous intensity of the intrinsic spectrum of each light-emitting unit 30 at 490 nm may be the same or different, which is not limited in the embodiments of the present disclosure.

For example, the luminous intensity of the intrinsic spectrum of the at least part of light-emitting units 30 at 490 nm may be 0.1, 0.15, 0.2, 0.25 or 0.35, which is not limited in the embodiments of the present disclosure.

In this way, the intensity of the intrinsic spectrum of the at least part of light-emitting units 30 is weak in a long wavelength band (i.e., the spectrum to the right of the peak of the intrinsic spectrum of the light-emitting unit 30), so that the enhancement of the intrinsic spectrum of the light-emitting device 300 in the long wavelength band is reduced, the color shift of the display panel 1000 is reduced, and the viewing effect of the viewer is improved.

In some embodiments, as shown in FIGS. 4 and 5, the light-emitting device 300 further includes an optical coupling layer 50. The optical coupling layer 50 is located on a side of the second electrode 20 away from the first electrode 10.

For example, the optical coupling layer 50 can allow a part of light to pass through and can also reflect a part of light.

Optionally, the light transmittance of the optical coupling layer 50 is in a range from 50% to 70%; and the light reflectivity of the optical coupling layer 50 is in a range from 30% to 50%.

For example, the light-emitting layer 50 may be made of a material with a high refractive index, such as one or a mixture of at least two of ZnSe, TiO₂, SiO₂, Si₃N₄, and Alq₃.

For example, the optical coupling layer 50 is located on the second electrode 20, which is used to protect the second electrode 20 and can also be used to improve the light extraction efficiency of the light-emitting device 300. On this basis, the material of the optical coupling layer 50 has characteristics of high refractive index and low light absorption coefficient, which is conducive to improving the light extraction effect of the light-emitting device 300. On this basis, the thickness of the optical coupling layer 50 may be changed to adjust a length of a microcavity, so as to modify the color shift and efficiency of the light-emitting device 300.

In some embodiments, the thickness of the second electrode 20 is greater than 12 nm; the thickness of the optical coupling layer 50 is h1, the refractive index of the optical coupling layer 50 is n, and h1 and n satisfy h1×n>150. For example, h1×n≥160; or h1×n≥170; or h1×n≥180, etc. The embodiments of the present disclosure do not limit this.

For example, the refractive index n of the optical coupling layer 50 may be in a range from 2 to 2.3; the thickness h1 of the optical coupling layer 50 may be greater than 75 nm. For example, the thickness h1 of the optical coupling layer 50 may be 76 nm, 80 nm, 82 nm, 84 nm or 86 nm.

For example, the thickness of the second electrode 20 is 13 nm, 14 nm, 15 nm, 16 nm or 17 nm, which is not limited in the embodiments of the present disclosure.

For example, the value of h1×n is 152, 154, 156, 158 or 160, which is not limited in the embodiments of the present disclosure.

In this way, when the display panel 1000 displays images, the light-emitting device 300 has a microcavity with longer length and has a stronger microcavity effect, so that the spectrum of the light-emitting device 300 is more obviously enhanced at the main peak position, and in turn the problem that the display panel 1000 is prone to color shift under a large viewing angle is effectively ameliorated, and the viewing effect of the viewer is improved.

It should be noted that a microcavity refers to a cavity structure with a certain thickness created between two layer structures with light reflection function in an OLED light-emitting device. After light enters the OLED light-emitting device, it will continuously reflect back and forth in the microcavity to achieve the resonance of the microcavity, thereby achieving the enhancement effect of light of a specific wavelength in the emitted light (namely, the microcavity effect).

The length of the microcavity refers to a distance between two layer structures with light reflection function. When the light-emitting device 300 provided in this embodiment is a top-emission OLED unit, the first electrode 10 is an anode which is opaque and capable of reflecting light, and the optical coupling layer 50 can also be used to reflect part of light. In this case, the distance between the light coupling layer 50 and the first electrode 10 is the microcavity length of the light-emitting device 300. The optical coupling layer 50 is located on the side of the second electrode 20 away from the first electrode 10. The greater the thickness of the second electrode 20, the longer the length of the microcavity of the light-emitting device 300, and the stronger the microcavity effect of the light-emitting device 300. Therefore, the spectrum of the light-emitting device 300 is more obviously enhanced at the main peak position.

In some examples, the thickness of the second electrode 20 of the light-emitting device 300 is greater than 12 nm; the thickness of the optical coupling layer 50 is h1, the refractive index of the optical coupling layer 50 is n, and h1 and n satisfy: h1×n>150. The N light-emitting units 30 include the first light-emitting unit 31 and the second light-emitting unit 32; the peak of the intrinsic spectrum of the first light-emitting unit 31 is λ1, and the full width at half maximum of the intrinsic spectrum of the first light-emitting unit 31 is FWHM1; the luminous intensity of the intrinsic spectrum of the first light-emitting unit 31 at 490 nm is λ1; the peak of the intrinsic spectrum of the second light-emitting unit 32 is λ2, and the full width at half maximum of the intrinsic spectrum of the second light-emitting unit 32 is FWHM2; and the luminous intensity of the intrinsic spectrum of the second light-emitting unit 32 at 490 nm is λ2.

Here, λ1=λ2 and λ1>465 nm; FWHM1=FWHM2 and FWHM1>30 nm; and λ1=λ2 and λ1>0.4.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1′=λ2′ and λ1′>465 nm; FWHM1′=FWHM2′ and FWHM1′>30 nm; and λ1′=λ2′ and λ1′>0.4.

A schematic diagram of color shift comparison shown in FIG. 7 can be obtained after testing. As can be seen from FIG. 7, by comparing the light-emitting device 300 (e.g., device 1 in FIG. 7) with the reference light-emitting device (e.g., the normal device in FIG. 7), the range of the difference between the color coordinate y value of the light-emitting device 300 under the blue image at a large viewing angle (for example, a viewing angle of 60°) and the color coordinate y value of the light-emitting device 300 under the blue image at the viewing angle of 0° decreases, and the color coordinate y value of the light-emitting device 300 under the blue image at a large viewing angle (for example, a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 5% compared to the reference light-emitting device.

In some embodiments of the present disclosure, the limitation on the range of the peak of the intrinsic spectrum of the light-emitting unit 30, the limitation on the range of the FWHM of the intrinsic spectrum of the light-emitting unit 30, and the limitation on the range of the luminous intensity of the intrinsic spectrum of the light-emitting unit 30 at 490 nm can be combined arbitrarily; in practical applications, those skilled in the art can choose to use one or more of the above limitations according to actual conditions.

For example, a peak of an intrinsic spectrum of a light-emitting unit 30 in the N light-emitting units 30 close to the first electrode 10 is in a range from 450 nm to 470 nm, and the sum of the peaks of the intrinsic spectra of the N light-emitting units 30 is in a range from N×450 nm to N×470 nm; an FWHM of the intrinsic spectrum of the light-emitting unit 30 close to the first electrode 10 is in a range from 10 nm to 30 nm, and the sum of the FWHMs of the intrinsic spectra of the N light-emitting units 30 is in a range from N×10 nm to N×30 nm; a luminous intensity of the intrinsic spectrum of the light-emitting unit 30 close to the first electrode 10 at 490 nm is in a range from 0 to 0.4, and the sum of the luminous intensities of the intrinsic spectra of the N light-emitting units 30 at 490 nm is in a range from 0 to N×0.4.

Therefore, the peak of the intrinsic spectrum of the at least part of light-emitting units 30 is in a range from 450 nm to 470 nm, the wavelength corresponding to the peak of the intrinsic spectrum of the at least part of light-emitting units 30 is small, so that the spectral enhancement at the main peak position of the spectrum of the light-emitting device 300 is more obvious; correspondingly, the spectral enhancement at the non-main peak position of the spectrum of the light-emitting device 300 is weakened. In addition, the non-main peak position of the intrinsic spectrum of the light-emitting device 300 is close to the left of the peak of the intrinsic spectrum, so that the enhancement at the non-main peak position of the spectrum of the light-emitting device 300 is weakened, and the color shift of the display panel 1000 at a large viewing angle is reduced.

In some examples, when the N light-emitting units 30 include the first light-emitting unit 31 and the second light-emitting unit 32, the peak of the intrinsic spectrum of the first light-emitting unit 31 is λ1, and the FWHM of the intrinsic spectrum of the first light-emitting unit 31 is FWHM1; the peak of the intrinsic spectrum of the second light-emitting unit 32 is λ2, and the FWHM of the intrinsic spectrum of the second light-emitting unit 32 is FWHM2.

Here, 450 nm<λ1<470 nm, λ1=λ2, and 900 nm<(λ1+λ2)<940 nm; and 10 nm<FWHM1<30 nm, FWHM1=FWHM2, and 20 nm<(FWHM1+FWHM2)<60 nm.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1′=λ2′ and λ1′>465 nm; FWHM1′=FWHM2′ and FWHM1′>30 nm; and λ1′=λ2′ and λ1′>0.4.

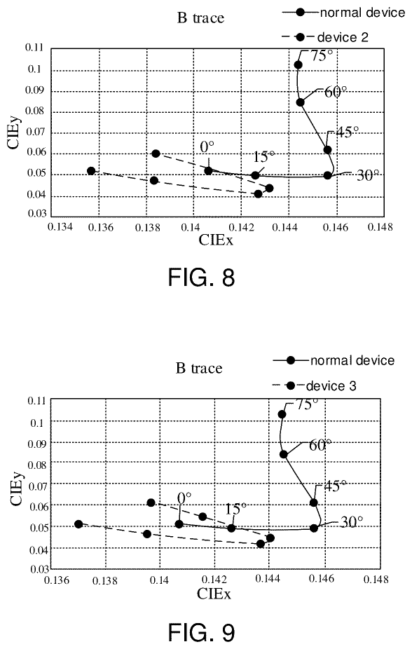

A schematic diagram of color shift comparison shown in FIG. 8 can be obtained after testing. It can be seen from FIG. 8 that, by comparing the light-emitting device 300 (e.g., the device 2 in FIG. 8) with the reference light-emitting device (e.g., the normal device in FIG. 8), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 18% compared to the light-emitting efficiency of the reference light-emitting device.

In some other embodiments, when the N light-emitting units 30 include the first light-emitting unit 31 and the second light-emitting unit 32, the peak λ1 of the intrinsic spectrum of the first light-emitting unit 31 and the peak λ2 of the intrinsic spectrum of the second light-emitting unit 32 satisfy: 450 nm<λ1<470 nm, λ1≠λ2, and 900 nm<(λ1+λ2)<940 nm; the full width at half maximum FWHM1 of the intrinsic spectrum of the first light-emitting unit 31 and the full width at half maximum FWHM2 of the intrinsic spectrum of the second light-emitting unit 32 satisfy: 10 nm<FWHM1<30 nm, FWHM1≠FWHM2, and 20 nm<(FWHM1+FWHM2)<60 nm.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1′=λ2′ and λ1′>465 nm; FWHM1′=FWHM2′ and FWHM1′>30 nm; and λ1′=λ2′ and λ1′>0.4.

A schematic diagram of color shift comparison shown in FIG. 9 can be obtained after testing. It can be seen from FIG. 9 that, by comparing the light-emitting device 300 (e.g., the device 3 in FIG. 9) with the reference light-emitting device (e.g., the normal device in FIG. 9), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 37% compared to the light-emitting efficiency of the reference light-emitting device.

In some other embodiments, the peak λ1 of the intrinsic spectrum of the first light-emitting unit 31 and the peak λ2 of the intrinsic spectrum of the second light-emitting unit 32 satisfy: 450 nm<λ1<470 nm and 900 nm<(λ1+λ2)<940 nm; the full width at half maximum FWHM1 of the intrinsic spectrum of the first light-emitting unit 31 and the full width at half maximum FWHM2 of the intrinsic spectrum of the second light-emitting unit 32 satisfy: 10 nm<FWHM1<30 nm and 20 nm<(FWHM1+FWHM2)<60 nm; the luminous intensity of the intrinsic spectrum of the first light-emitting unit 31 at 490 nm is λ1, the luminous intensity of the intrinsic spectrum of the second light-emitting unit 32 at 490 nm is λ2, and λ1 and λ2 satisfy: 0<λ1<0.4, 0<(λ1+λ2)<0.8, and λ1=λ2.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1l′=λ2′ and λ1′>465 nm; FWHM1′=FWHM2′ and FWHM1′>30 nm; and λ1′=λ2′ and λ1′>0.4.

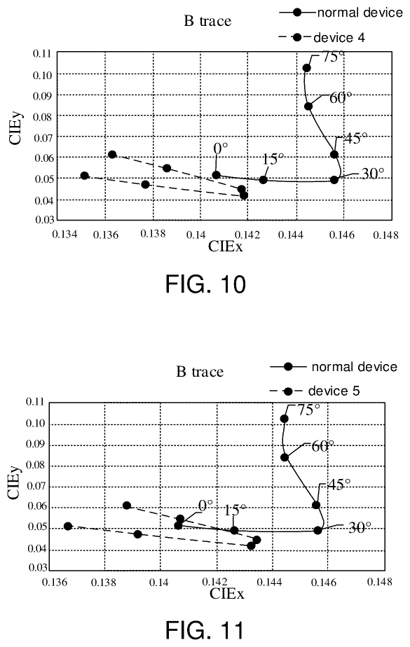

A schematic diagram of color shift comparison shown in FIG. 10 can be obtained after testing. It can be seen from FIG. 10 that, by comparing the light-emitting device 300 (e.g., the device 4 in FIG. 10) with the reference light-emitting device (e.g., the normal device in FIG. 10), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 20% compared to the light-emitting efficiency of the reference light-emitting device.

In some other embodiments, the peak λ1 of the intrinsic spectrum of the first light-emitting unit 31 and the peak λ2 of the intrinsic spectrum of the second light-emitting unit 32 satisfy: 450 nm<λ1<470 nm and 900 nm<(λ1+λ2)<940 nm; the full width at half maximum FWHM1 of the intrinsic spectrum of the first light-emitting unit 31 and the full width at half maximum FWHM2 of the intrinsic spectrum of the second light-emitting unit 32 satisfy: 10 nm<FWHM1<30 nm and 20 nm<(FWHM1+FWHM2)<60 nm; the luminous intensity of the intrinsic spectrum of the first light-emitting unit 31 at 490 nm is λ1, the luminous intensity of the intrinsic spectrum of the second light-emitting unit 32 at 490 nm is λ2, and λ1 and λ2 satisfy: 0<λ1<0.4, 0<(λ1+λ2)<0.8, and λ1≠λ2.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1′=λ2′ and λ1′>465 nm; FWHM1′=FWHM2′ and FWHM1′>30 nm; and λ1′=λ2′ and λ1′>0.4.

A schematic diagram of color shift comparison shown in FIG. 11 can be obtained after testing. It can be seen from FIG. 11 that, by comparing the light-emitting device 300 (e.g., the device 5 in FIG. 11) with the reference light-emitting device (e.g., the normal device in FIG. 11), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 37% compared to the light-emitting efficiency of the reference light-emitting device.

In some other embodiments, the peak λ1 of the intrinsic spectrum of the first light-emitting unit 31 and the peak λ2 of the intrinsic spectrum of the second light-emitting unit 32 satisfy: 450 nm<λ2<470 nm, λ1≠λ2, and 900 nm<(λ1+λ2)<940 nm; the full width at half maximum FWHM1 of the intrinsic spectrum of the first light-emitting unit 31 and the full width at half maximum FWHM2 of the intrinsic spectrum of the second light-emitting unit 32 satisfy: 10 nm<FWHM2<30 nm, FWHM1≠FWHM2, 20 nm<(FWHM1+FWHM2)<60 nm.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1l′=λ2′ and λ1′>465 nm; FWHM1′=FWHM2′ and FWHM1′>30 nm; and λ1′=λ2′ and λ1′>0.4.

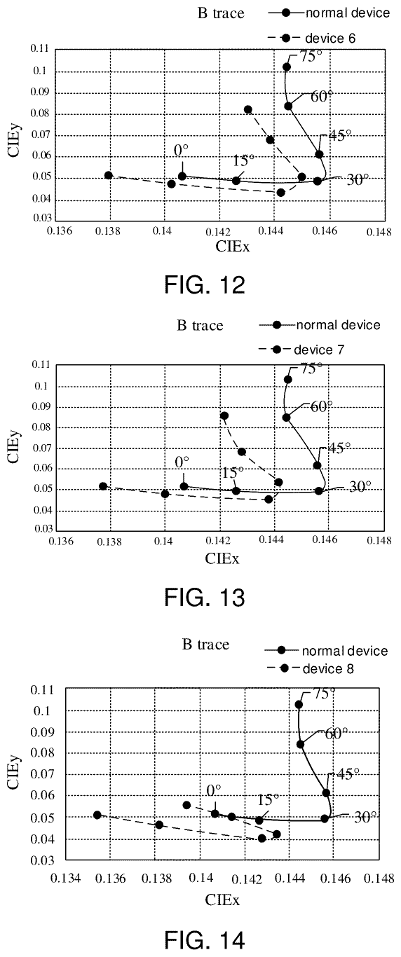

A schematic diagram of color shift comparison shown in FIG. 12 can be obtained after testing. It can be seen from FIG. 12 that, by comparing the light-emitting device 300 (e.g., the device 6 in FIG. 12) with the reference light-emitting device (e.g., the normal device in FIG. 12), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.07, which effectively ameliorates the problem that the light-emitting device 300 is prone to color shift at a large viewing angle, and improves the viewing effect of the viewer; on this basis, the light-emitting efficiency of the light-emitting device 300 is increased by about 42% compared to the light-emitting efficiency of the reference light-emitting device.

In some embodiments, the peak λ1 of the intrinsic spectrum of the first light-emitting unit 31 and the peak λ2 of the intrinsic spectrum of the second light-emitting unit 32 satisfy: 450 nm<λ2<470 nm and 900 nm<(λ1+λ2)<940 nm; the full width at half maximum FWHM1 of the intrinsic spectrum of the first light-emitting unit 31 and the full width at half maximum FWHM2 of the intrinsic spectrum of the second light-emitting unit 32 satisfy: 10 nm<FWHM2<30 nm and 20 nm<(FWHM1+FWHM2)<60 nm; the luminous intensity of the intrinsic spectrum of the first light-emitting unit 31 at 490 nm is λ1, the luminous intensity of the intrinsic spectrum of the second light-emitting unit 32 at 490 nm is λ2, and λ1 and λ2 satisfy: 0<λ2<0.4, 0<(λ1+λ2)<0.8, and λ1≠λ2.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1l′=λ2′ and λ1′>465 nm; FWHM1′=FWHM2′ and FWHM1′>30 nm; and λ1′=λ2′ and λ1′>0.4.

A schematic diagram of color shift comparison shown in FIG. 13 can be obtained after testing. It can be seen from FIG. 13 that, by comparing the light-emitting device 300 (e.g., the device 7 in FIG. 13) with the reference light-emitting device (e.g., the normal device in FIG. 13), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.07, which effectively ameliorates the problem that the light-emitting device 300 is prone to color shift at a large viewing angle, and improves the viewing effect of the viewer; on this basis, the light-emitting efficiency of the light-emitting device 300 is increased by about 43% compared to the light-emitting efficiency of the reference light-emitting device.

In some embodiments, as shown in FIG. 5, there are three light-emitting units 30, the three light-emitting units 30 are respectively a first light-emitting unit 31, a second light-emitting unit 32 and a third light-emitting unit 33, and the first light-emitting unit 31, the second light-emitting unit 32 and the third light-emitting unit 33 are sequentially away from the first electrode 10. For example, the first light-emitting unit 31 is in direct contact with the first electrode 10, the second light-emitting unit 32 is located between the first light-emitting unit 31 and the third light-emitting unit 33, and the third light-emitting unit 33 is in direct contact with the second electrode 20.

For example, the third light-emitting unit 33 includes a third light-emitting layer EML3. For example, the third light-emitting layer EML3 is a blue light-emitting layer for emitting blue light.

Optionally, the material of the third light-emitting layer EML3 may include anthracene compounds, fluorene compounds, or styrene compounds.

Optionally, the third light-emitting unit 33 further includes at least one of a third hole injection layer, a third hole transport layer, a third electron blocking layer, a third hole blocking layer, a third electron transport layer, or a third electron injection layer.

The third electron injection layer can reduce the injection barrier of electrons, the third electron transport layer can improve the transportability of electrons, the third electron blocking layer can hinder the transportability of electrons, the third hole blocking layer can hinder the transportability of holes, the third hole transport layer can improve the transportability of holes, and the third hole injection layer can reduce the injection barrier of holes.

Optionally, the thickness of the third electron injection layer included in the third light-emitting unit 33 may be in a range from 1 nm to 3 nm, the thickness of the third electron transport layer may be in a range from 20 nm to 35 nm, the thickness of the third hole blocking layer may be in a range from 5 nm to 10 nm, the thickness of the third light-emitting layer EML3 may be in a range from 20 nm to 40 nm, the thickness of the third electron blocking layer may be in a range from 10 nm to 80 nm, the thickness of the third hole transport layer may be in a range from 1000 nm to 1300 nm, and the thickness of the third hole injection layer may be in a range from 5 nm to 30 nm. If the thicknesses of all layers change within the above thickness ranges, the color of the emitted light will change within the same color system. For example, when the light emitted by the third light-emitting layer EML3 is blue light and the thickness of the third electron transport layer ETL3 is 30 nm, if the thickness of the third electron transport layer ETL3 changes from 30 nm to 25 nm, then the light emitted by the third light-emitting layer EML3 may change from blue to light blue; correspondingly, if the thickness of the third electron transport layer ETL3 changes from 30 nm to 33 nm, then the light emitted by the third light-emitting layer EML3 may change from blue to dark blue.

For example, as shown in FIG. 5, the third light-emitting unit 33 further includes a third electron transport layer ETL3 and a third hole transport layer HTL3. The third electron transport layer ETL3 is located between the third light-emitting layer EML3 and the second electrode 20, and the third electron transport layer ETL3 is used for transporting electrons from the second electrode 20 to the third light-emitting layer EML3.

The third hole transport layer HTL3 is located between the third light-emitting layer EML3 and the second light-emitting unit 32. The third hole transport layer HTL3 is used for transporting holes to the third light-emitting layer EML3. In this way, holes and electrons can recombine in the third light-emitting layer EML3, so that the third light-emitting layer EML3 emits light.

The third electron transport layer ETL3 may be a zinc oxide-based nanoparticle film or a zinc oxide film. In addition, when the third electron transport layer ETL3 is a zinc oxide-based nanoparticle film, the third electron transport layer ETL3 may also use ion-doped zinc oxide nanoparticles, such as magnesium (Mg), indium (In), aluminum (Al), or gallium (Ga) doped magnesium oxide nanoparticles.

The material of the third hole transport layer HTL3 may include at least one of molybdenum oxide, nickel oxide, zirconium oxide or vanadium oxide, which is not specifically limited in the embodiments of the present disclosure. It should be noted that molybdenum oxide includes molybdenum oxide, molybdenum dioxide and molybdenum trioxide, and nickel oxide includes nickel oxide and nickel trioxide. Zirconium oxide includes zirconium dioxide. Vanadium oxide includes vanadium monoxide, vanadium trioxide, vanadium dioxide, and vanadium pentoxide, which will not be limited in the embodiments of the present disclosure.

For example, the specific structure of the third light-emitting unit 33 and the specific structures of the first light-emitting unit 31 and the second light-emitting unit 32 may be the same or different, which will not be limited in the embodiments of the present disclosure. For example, as shown in FIG. 5, the structures of the first light-emitting unit 31, the second light-emitting unit 32 and the third light-emitting unit 33 are the same.

In some examples, the peak of the intrinsic spectrum of the third light-emitting unit 33 is λ3, the FWHM of the intrinsic spectrum of the third light-emitting unit 33 is FWHM3, and the luminous intensity of the intrinsic spectrum of the third light-emitting unit 33 at 490 nm is λ3.

The peak λ1 of the intrinsic spectrum of the first light-emitting unit 31, the peak λ2 of the intrinsic spectrum of the second light-emitting unit 32, and the peak λ3 of the intrinsic spectrum of the third light-emitting unit 33 satisfy: 450 nm<λ1<470 nm and 1350 nm<(λ1+λ2+λ3)<1410 nm; the full width at half maximum FWHM1 of the intrinsic spectrum of the first light-emitting unit 31, the full width at half maximum FWHM2 of the intrinsic spectrum of the second light-emitting unit 32, and the full width at half maximum FWHM2 of the intrinsic spectrum of the third light-emitting unit 33 satisfy: 10 nm<FWHM1<30 nm and 30 nm<(FWHM1+FWHM2+FWHM3)<90 nm; the luminous intensity λ1 of the intrinsic spectrum of the first light-emitting unit 31 at 490 nm, the luminous intensity λ2 of the intrinsic spectrum of the second light-emitting unit 32 at 490 nm, and the luminous intensity λ3 of the intrinsic spectrum of the third light-emitting unit 33 at 490 nm satisfy: 0<λ1<0.4 and 0<(λ1+λ2+λ3)<1.2.

In some embodiments of the present disclosure, the light-emitting device 300 and a reference light-emitting device are tested and compared.

The thickness of the second electrode 20 of the reference light-emitting device is less than 12 nm, and the thickness h1′ of the optical coupling layer 50 and the refractive index n′ of the optical coupling layer 50 satisfy: h1′×n′<150. The reference light-emitting device includes a first light-emitting unit 31 and a second light-emitting unit 32; the peak of the intrinsic spectrum of the first light-emitting unit 31 is λ1′, and the full width at half maximum of the intrinsic spectrum of the first light-emitting unit 31 is FWHM1′; the luminous intensity of the intrinsic spectrum of the first light-emitting unit 31 at 490 nm is λ1′; the peak of the intrinsic spectrum of the second light-emitting unit 32 is λ2′, and the full width at half maximum of the intrinsic spectrum of the second light-emitting unit 32 is FWHM2′; and the luminous intensity of the intrinsic spectrum of the second light-emitting unit 32 at 490 nm is λ2′.

Here, λ1′=λ2′ and λ1′>465 nm; FWHM1′=FWHM2′ and FWHM1′>30 nm; and λ1′=λ2′ and λ1′>0.4.

A schematic diagram of color shift comparison shown in FIG. 14 can be obtained after testing. It can be seen from FIG. 14 that, by comparing the light-emitting device 300 (e.g., the device 8 in FIG. 14) with the reference light-emitting device (e.g., the normal device in FIG. 14), the range of the difference between the color coordinate y value of the light-emitting device 300 under the blue image at a large viewing angle (e.g., a viewing angle of 60°) and the color coordinate y value of the light-emitting device 300 under the blue image at the viewing angle of 0° decreases, and the color coordinate y value of the light-emitting device 300 under the blue image at a large viewing angle (e.g., a viewing angle of 60°) is less than 0.06, which effectively ameliorates the problem that the light-emitting device 300 is prone to color shift at a large viewing angle, and improves the viewing effect of the viewer; on this basis, the light-emitting efficiency of the light-emitting device 300 is increased by about 24% compared to the light-emitting efficiency of the reference light-emitting device.

In some examples, as shown in FIGS. 4 and 5, the light-emitting device 300 further includes an encapsulation layer 60. The encapsulation layer 60 is located on a side of the light coupling layer 50 away from the second electrode 20.

For example, the encapsulation layer 60 may be an encapsulation thin film (in which case, a thin film encapsulation (TFE) is used), or may be an encapsulation substrate. The encapsulation layer 60 can encapsulate the N light-emitting units 30, which avoids that water and oxygen corrode the N light-emitting units 30 to affect the light-emitting efficiency and service life of the light-emitting device 300.

For example, the encapsulation layer 60 includes a first inorganic layer, an organic layer and a second inorganic layer that are stacked in sequence. The first inorganic layer and the second inorganic layer play a main role in blocking the intrusion of water and/or oxygen into the N light-emitting units 30, and the organic layer plays a role in assisting encapsulation and planarization.

For example, the first inorganic layer and the second inorganic layer may be made of inorganic materials such as nitride, oxide, oxynitride, nitrate, carbide or any combination thereof. The organic layer may be made of acrylic, hexamethyldisiloxane, polyacrylate, polycarbonate, polystyrene, or other materials.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode;
a second electrode;
N light-emitting units stacked between the first electrode and the second electrode; and
a connection layer disposed between any two adjacent light-emitting units;
wherein a peak of an intrinsic spectrum of at least part of light-emitting units in the N light-emitting units is in a range from 400 nm to 480 nm; a sum of peaks of intrinsic spectra of the N light-emitting units is in a range from N×400 nm to N×480 nm; N is greater than or equal to 2, and N is a positive integer; and
a difference between a color coordinate y value of the light-emitting device under a blue image at a preset viewing angle that is in a range from 600 to 750 and a color coordinate y value of the light-emitting device under the blue image at a viewing angle of 0° is in a range from 0 to 0.07.

2. The light-emitting device according to claim 1, wherein the color coordinate y value of the light-emitting device under the blue screen at the preset viewing angle is less than 0.07.

3. The light-emitting device according to claim 1, wherein
the peak of the intrinsic spectrum of the at least part of light-emitting units is in a range from 450 nm to 470 nm; and the sum of the peaks of the intrinsic spectra of the N light-emitting units is in a range from N×450 nm to N×470 nm.

4. The light-emitting device according to claim 3, wherein in the at least part of light-emitting units, a peak of an intrinsic spectrum of each light-emitting unit is the same, and the peak of the intrinsic spectrum of each light-emitting unit is in a range from 450 nm to 470 nm.

5. The light-emitting device according to claim 1, wherein a full width at half maximum of the intrinsic spectrum of the at least part of light-emitting units is in a range from 10 nm to 30 nm; and a sum of full widths at half maxima of the intrinsic spectra of the N light-emitting units is in a range from N×10 nm to N×30 nm.

6. The light-emitting device according to claim 5, wherein in the at least part of light-emitting units, a full width at half maximum of an intrinsic spectrum of each light-emitting unit is the same, and the full width at half maximum of the intrinsic spectrum of each light-emitting unit is in a range from 10 nm to 30 nm.

7. The light-emitting device according to a claim 1, wherein a luminous intensity of the intrinsic spectrum of the at least part of light-emitting units at 490 nm is in a range from 0 to 0.4, and a sum of luminous intensities of the intrinsic spectra of the N light-emitting units at 490 nm is in a range from 0 to N×0.4.

8. The light-emitting device according to claim 1, wherein a number of the N light-emitting units is two, and the two light-emitting units are respectively a first light-emitting unit and a second light-emitting unit, and the first light-emitting unit and the second light-emitting unit are sequentially away from the first electrode;
wherein a peak of an intrinsic spectrum of the first light-emitting unit is λ1, a peak of an intrinsic spectrum of the second light-emitting unit is λ2, and λ1 and λ2 satisfy: 450 nm<λ1<470 nm, 900 nm<(λ1+λ2)<940 nm, and λ1≠λ2;
a full width at half maximum of the intrinsic spectrum of the first light-emitting unit is different from a full width at half maximum of the intrinsic spectrum of the second light-emitting unit; the full width at half maximum of the first light-emitting unit is in a range from 10 nm to 30 nm; and a sum of the full width at half maximum of the first light-emitting unit and the full width at half maximum of the second light-emitting unit is in a range from 20 nm to 60 nm.

9. The light-emitting device according to claim 8, wherein
a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ1<0.4, 0<(λ1+λ2)<0.8, and λ1=λ2.

10. The light-emitting device according to claim 8, wherein
a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ1<0.4, 0<(λ1+λ2)<0.8, and λ1≠λ2.

11. The light-emitting device according to claim 1, wherein a number of the N light-emitting units is two, and the two light-emitting units are respectively a first light-emitting unit and a second light-emitting unit, and the first light-emitting unit and the second light-emitting unit are sequentially away from the first electrode;
wherein a peak of an intrinsic spectrum of the first light-emitting unit is λ1, a peak of an intrinsic spectrum of the second light-emitting unit is λ2, and λ1 and λ2 satisfy: 450 nm<λ2<470 nm, 900 nm<(λ1+λ2)<940 nm, and λ1≠λ2;
a full width at half maximum of the intrinsic spectrum of the first light-emitting unit is different from a full width at half maximum of the intrinsic spectrum of the second light-emitting unit; the full width at half maximum of the intrinsic spectrum of the second light-emitting unit is in a range from 10 nm to 30 nm; and a sum of the full width at half maximum of the first light-emitting unit and the full width at half maximum of the second light-emitting unit is in a range from 20 nm to 60 nm.

12. The light-emitting device according to claim 11, wherein
a luminous intensity of the intrinsic spectrum of the first light-emitting unit at 490 nm is λ1, a luminous intensity of the intrinsic spectrum of the second light-emitting unit at 490 nm is λ2, and λ1 and λ2 satisfy: 0<λ2<0.4, 0<(λ1+λ2)<0.8, and λ1≠λ2.

13. The light-emitting device according to claim 1, wherein a number of the N light-emitting units is three, and the three light-emitting units are respectively a first light-emitting unit, a second light-emitting unit and a third light-emitting unit; the first light-emitting unit, the second light-emitting unit and the third light-emitting unit are sequentially away from the first electrode;
wherein a peak of an intrinsic spectrum of the first light-emitting unit is λ1, a peak of an intrinsic spectrum of the second light-emitting unit is λ2, a peak of an intrinsic spectrum of the third light-emitting unit is λ3, and λ1, λ2 and λ3 satisfy: 450 nm<λ1<470 nm, 1350 nm<(λ1+λ2+λ3)<1410 nm;
a full width at half maximum of the intrinsic spectrum of the first light-emitting unit is in a range from 10 nm to 30 nm; a sum of the full width at half maximum of the intrinsic spectrum of the first light-emitting unit, a full width at half maximum of the intrinsic spectrum of the second light-emitting unit and a full width at half maximum of the intrinsic spectrum of the third light-emitting unit is in a range from 30 nm to 90 nm;
a luminous intensity of the intrinsic spectrum of the first light-emitting unit at 490 nm is λ1, a luminous intensity of the intrinsic spectrum of the second light-emitting unit at 490 nm is λ2, a luminous intensity of the intrinsic spectrum of the third light-emitting unit at 490 nm is λ3, and λ1, λ2 and λ3 satisfy: 0<λ1<0.4 and 0<(λ1+λ2+λ3)<1.2.

14. The light-emitting device according to claim 1, wherein a peak of an intrinsic spectrum of a light-emitting unit close to the first electrode is in a range from 450 nm to 470 nm; and the sum of the peaks of the intrinsic spectra of the N light-emitting units is in a range from N×450 nm to N×470 nm;
a full width at half maximum of the intrinsic spectrum of the light-emitting unit close to the first electrode is in a range from 10 nm to 30 nm; and a sum of full widths at half maxima of the intrinsic spectra of the N light-emitting units is in a range from N×10 nm to N×30 nm;
a luminous intensity at 490 nm of the intrinsic spectrum of the light-emitting unit close to the first electrode is in a range from 0 to 0.4, and a sum of luminous intensities of the intrinsic spectra of the N light-emitting units at 490 nm is in a range from 0 to N×0.4 r.

15. The light-emitting device according to claim 1, further comprising an optical coupling layer located on a side of the second electrode away from the first electrode.

16. The light-emitting device according to claim 15, wherein a thickness of the second electrode is greater than 12 nm;
a thickness of the optical coupling layer is h1, a refractive index of the optical coupling layer is n, and h1 and n satisfy:
h1×n>150.

17. A display panel, comprising:
a substrate; and
a plurality of sub-pixels disposed on the substrate;
wherein at least one sub-pixel includes the light-emitting device according to claim 1.

18. A display apparatus, comprising the display panel according to claim 17.

19. The light-emitting device according to claim 2, wherein the peak of the intrinsic spectrum of the at least part of light-emitting units is in a range from 450 nm to 470 nm; and the sum of the peaks of the intrinsic spectra of the N light-emitting units is in a range from N×450 nm to N×470 nm.

20. The light-emitting device according to claim 3, wherein a full width at half maximum of the intrinsic spectrum of the at least part of light-emitting units is in a range from 10 nm to 30 nm; and a sum of full widths at half maxima of the intrinsic spectra of the N light-emitting units is in a range from N×10 nm to N×30 nm.
